(19) United States
(12) Patent Application Publication
(10) Pub. No.: US 2020/0382092 A1
(43) Pub. Date: Dec. 3, 2020

(54) METHODS OF MAKING ACOUSTIC WAVE DEVICES

(71) Applicants: Dong Li, San Ramon, CA (US); Ying Ma, Pleasanton, CA (US); Ge Yi, San Ramon, CA (US); Zongrong Liu, Pleasanton, CA (US)

(72) Inventors: Dong Li, San Ramon, CA (US); Ying Ma, Pleasanton, CA (US); Ge Yi, San Ramon, CA (US); Zongrong Liu, Pleasanton, CA (US)

(21) Appl. No.: 16/428,860

(22) Filed: May 31, 2019

(51) Int. Cl. H03H 9/02; H03H 9/17

(52) U.S. Cl. CPC H03H 9/02015; H03H 2003/0071; H03H 9/171

(57) ABSTRACT

An acoustic wave device system with its piezoelectric layer originating from a single crystal piezoelectric wafer/substrate is invented along with sets of detailed process steps to fabricate such a device using wafer-to-wafer and/or die-to-wafer bonding technologies. The proposed device system is particularly good to make bulk acoustic wave (BAW) devices. Methods allowing the single crystal piezoelectric wafer/substrate to be re-used are also given. The proposed methods include detailed process steps to allow heterogeneous integration of electrical chips into the system in a very cost efficient manner. The invention provides a practical and low-cost approach to fabricate the radio frequency (RF) front end chip incorporating RF filters and electronic components integrated into a small footprint which is particularly useful for mobile device and RF stations.

### FIELD OF INVENTION

The invention is related to thin film bulk acoustic devices. Particularly, a thin film bulk acoustic resonator comprises a piezoelectric material sandwiched between two electrodes, which is acoustically isolated from the surrounding medium.

### BACKGROUND ART

Since the smart phone prevailed, the mobile wireless supported by 4G LTE and incoming 5G has already made and will further make great change of people's ordinary lives. With incoming 5G to access more and higher frequency bands and also the increase of popularity of so-called full netcom smart phones, the demand for radio frequency(RF) filters in an individual device, or a wireless base station such as mobile tower or WiFi router will increase dramatically. There are also technical requirements for such kind of RF filters to be capable of handling even higher power. On top of all these requirements, there is another aspect, i.e. the cost and affordability. With the number of filters in RF front-end continually increasing, there is a great demand to further reduce the cost for individual filter or overall to maintain the same price range with better performance while keeping lower power assumption and smaller footprint, particularly for the incoming 5G technology. How to integrate many RF filters with different piezoelectric film thickness, preferably along with RF front-end electronic chip (e-chips), to meet the above mentioned requirements, is such a big challenge not only for design but even more importantly for process integration scheme/path, which provides ultimate manufacturability and affordability.

BAW filter devices are essentially two-terminal MEMS devices. There are two classes of RF filter technologies namely, surface acoustic wave (SAW) and bulk acoustic film (BAW) technologies. The BAW is much less affected by the temperature drafting and capable of being used in higher frequency band up to 10 GHz. BAW filters fall into two general architectures, solidly mounted resonators (SMR) and film bulk acoustic resonators (FBAR). AlN and ZnO are two widely used BAW materials. While polycrystalline films made by physical vapor deposition such as sputtering with controlled texture with column growth are more widely used in Avago's FBAR and Qorvo's SMR design, it is claimed by Akoustis that heterogeneous epitaxially grown single crystal AlN-based BAW devices provide better performance over Avago's FBAR and Qorvo's SMR. Nevertheless, all the three companies—Avago, Qorvo, and Akoustic—use wafer level MEMS processes as their methods for BAW devices fabrication.

In this disclosure, we propose a few novel process solutions and integration schemes based on wafer-to-wafer, and die-to-wafer bonding for BAW fabrication. The current disclosure is the first one among a series of inventions from us to provide overall solutions to bring down the cost of the RF frontend chiplet and module to meet incoming 5G network and even future 6G network for all netcom portable devices, base stations, and devices for wireless access points.

### SUMMARY OF THE INVENTION

In this invention, a new integration and process scheme is provided. It mainly uses wafer-to-wafer and die-to-wafer methods rather than conventional MEMS wafer level processes not only to manufacture the needed structures for the RF BAW filters but also simultaneously to enable wafer level packaging and testing, and even to enable the co-integration of multiple RF filters with their control electronic chips (e-chips).

Our proposed methods simplify greatly the process complex at both wafer and packaging levels, which bring the vast possibility to drastically reduce the RF filter and even overall RF front-end components' production cost. It can also extend the processes at wafer level to integrate the filter in hermetically sealed structures.

The proposed method can be universally adopted with piezoelectric materials from either single crystal wafers from suppliers using all sorts of different single crystal growth methods, or wafers made by our unique film growth methods using single crystal piezoelectric wafers as the substrate (or epitaxy growth template). The substrate or template can be recycled for re-use for cost saving purpose. The piezoelectric film quality from our methods is better than that from PVD methods used by Avago and Qorovo,

In our proposal, when the piezoelectric single crystal wafer is used, ion cut process eg. smart cut is used to enable the substrate reuse to lower the overall cost. Moreover, due to the precise dosage and implantation energy control, the ion cut process can accurately control the cut thickness with a range variation down to one to two nanometers, which greatly reduces the process cost and improves the yield when coming to filter frequency selection by the control of piezoelectric film thickness.

For the precise piezoelectric film thickness control, it is also proposed by using combination of ion implantation and selected wet etch to control the remaining piezoelectric thin film thickness, which could replace much more expensive process combination of lithographic patterning and reactive ion etch (RIE). Of course, a specially selected ion which provides the wet etch selectivity between the implanted and non-implanted parts has to be implanted into the piezoelectric material in a predetermined depth to achieve the target thickness post wet etch.

Using single crystal substrates as piezoelectric films growth templates, the films can have much better controlled crystal structure and crystal orientation very close to single crystal or with much bigger crystal sizes compared to film growth without a template. We also use either laser transfer process (LTP), or laser liftoff (LLO), or transfer printing, or similar alternatives to enable die-to-wafer or collective die to wafer transfer to reduce manufacture cost. Nevertheless, using the single crystal piezoelectric wafer is still the core of this invention.

The proposed method also includes heterogeneous integration of multiple RF filter chips with or without different RF front-end e-chips for either a colossal multiple filter chiplet or a fully integrated RF front-end chiplet with controlled e-chips included.

The proposed approach also enables the BAW filter cavity or cavities created at wafer level with vacuum pumping down pre-cavity sealing, which also greatly reduce any acoustic loss parallel to the bulk acoustic propagation direction.

Our proposed methods can meet all the above mentioned performance requirements and also provide our customers with much better value for their money to meet 5G and future 6G requirements.

Although the proposed methods are much more effective for BAW device fabrication, the similar approach can be used to fabricate SAW to cover the low bandwidth RF filters' functionality.

As used herein, the term “or” may be construed in either an inclusive or exclusive sense. Similarly, the term “exemplary” is construed merely to mean an example of something or an exemplar and not necessarily a preferred or ideal means of accomplishing a goal. Additionally, although various exemplary embodiments discussed below focus on quality control of professionals, the embodiments are given merely for clarity and disclosure. Alternative embodiment may employ other systems and methods and are considered as being within the scope of the present invention.

### BRIEF DESCRIPTION OF THE DRAWINGS

FIG. 1 an embodiment of a proposed wafer process flow using wafer to wafer bonding with one single crystal piezoelectric wafer to fabricate BAW devices with control electronic chips and packaging in one go.

FIG. 2 one of the embodiment of a proposed process flow to make BAW devices through wafer to wafer bonding using single crystal piezoelectric wafer processing without bonding layer covering the bottom electrode to further improve the acoustic energy loss of the device.

FIG. 3 an embodiment of a process flow of using a single crystal piezoelectric wafer as an epitaxy template for seeded epitaxy growth of the pizeoelectric layer for BAW device fabrication using wafer to wafer bonding approach.

FIG. 4 one of the embodiment of a process flow to make BAW devices via die to wafer bonding whose dies are obtained from dicing a handling wafer with functional piezoelectric layer transferred from a single crystal piezoelectric wafer.

FIG. 5 an embodiment of a process flow to make BAW via die to wafer bonding, whose dies are from diced single crystal piezoelectric wafers.

FIG. 6 an embodiment of a process flow to make BAW devices through die to wafer bonding whose dies are obtained from dicing a handling wafer, on which the transferred functional piezoelectric layer is obtained using a single crystal piezoelectric wafer as an epitaxy template for seeded epitaxy growth.

### DETAILED DESCRIPTION

The following numerous specific detail descriptions are set forth to provide a thorough understanding of various embodiments of the present disclosure. It will be apparent to one skilled in the art, however, that these specific details need not be employed to practice various embodiments of the present disclosure. In other instances, well known components or methods have not been described.

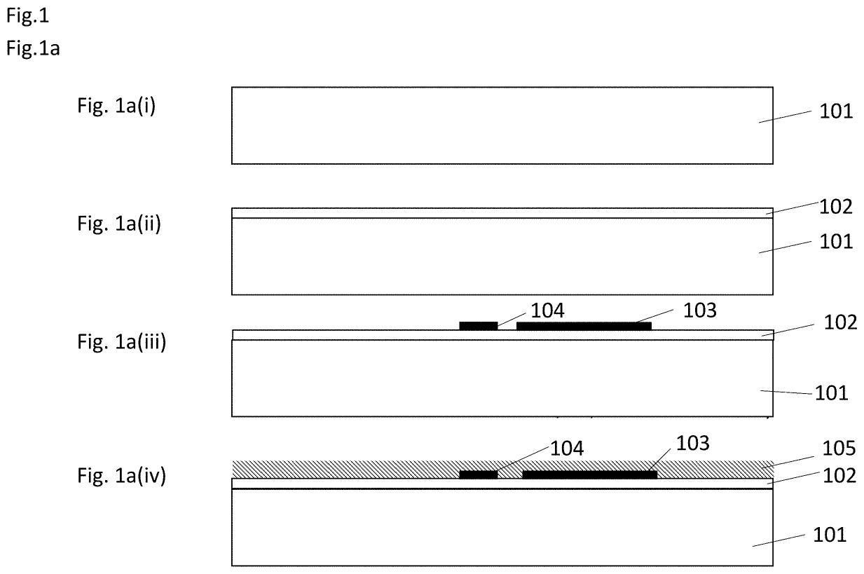

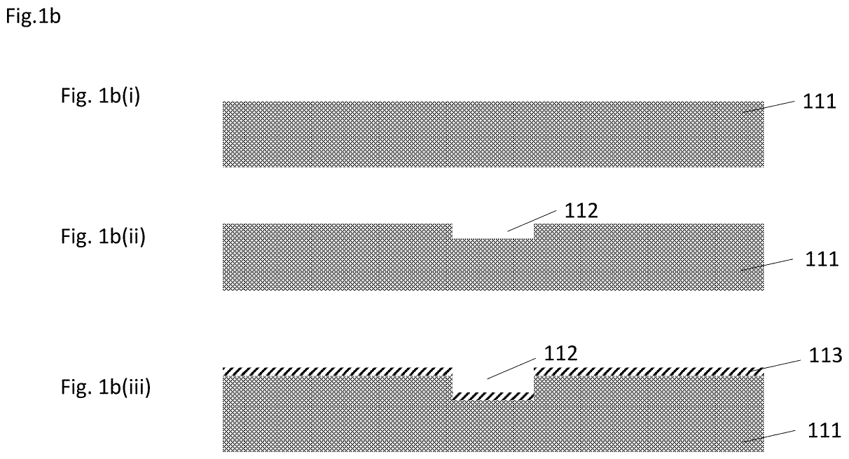

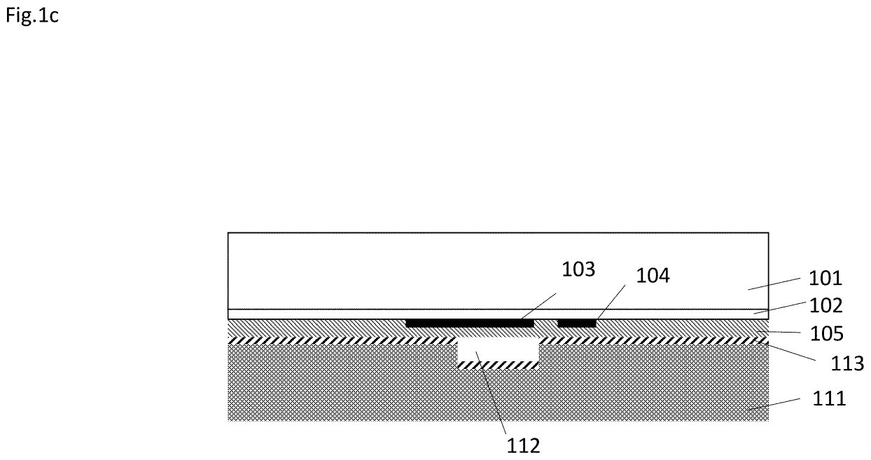

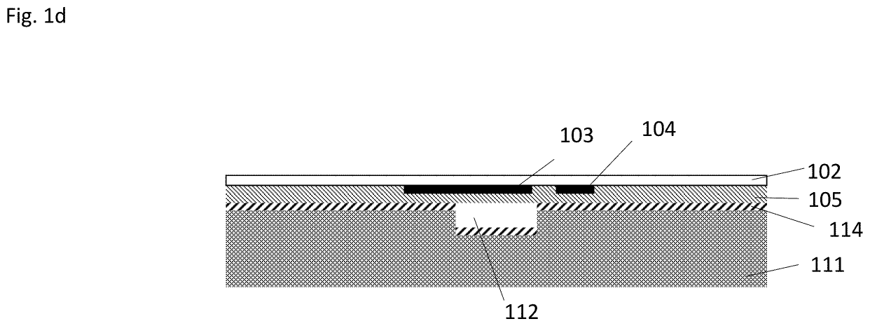

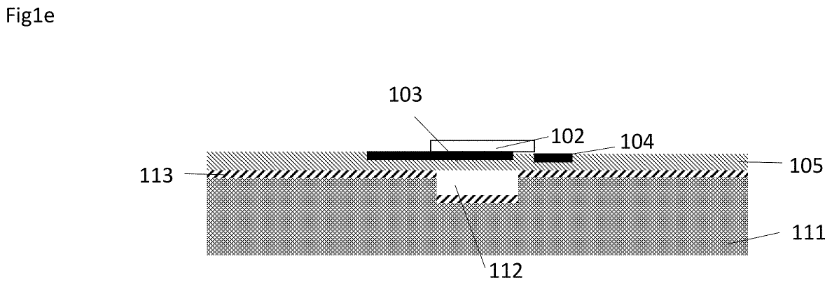

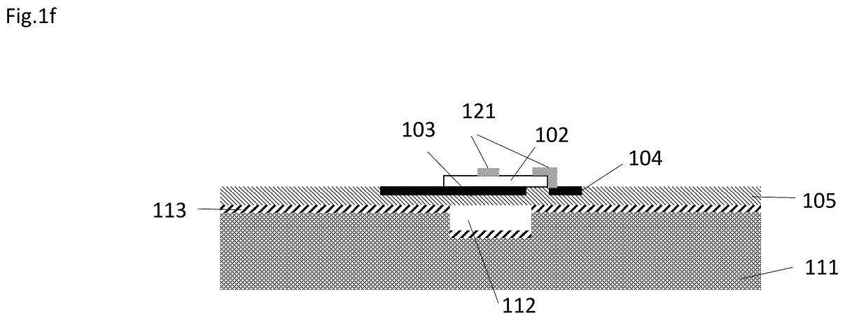

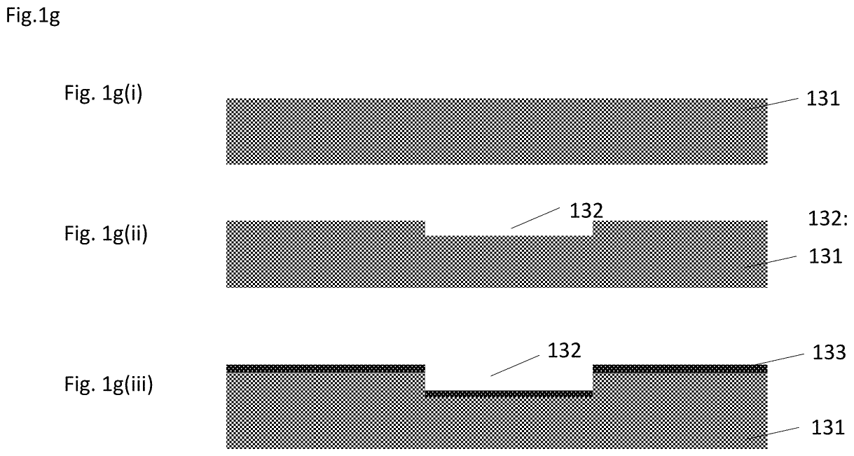

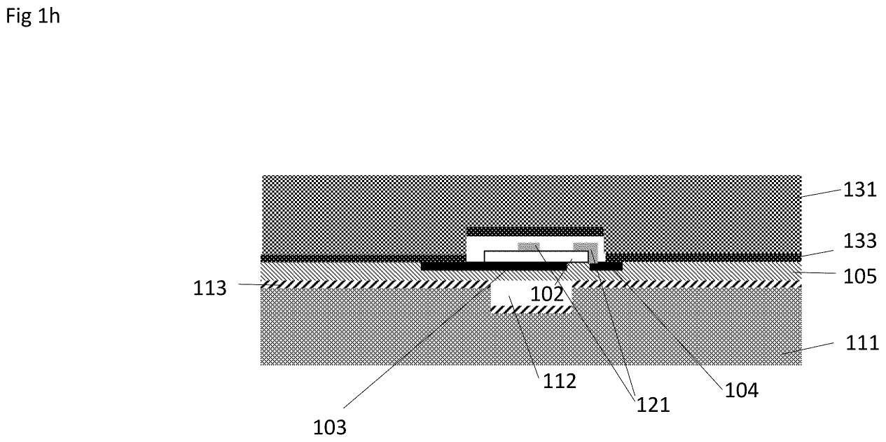

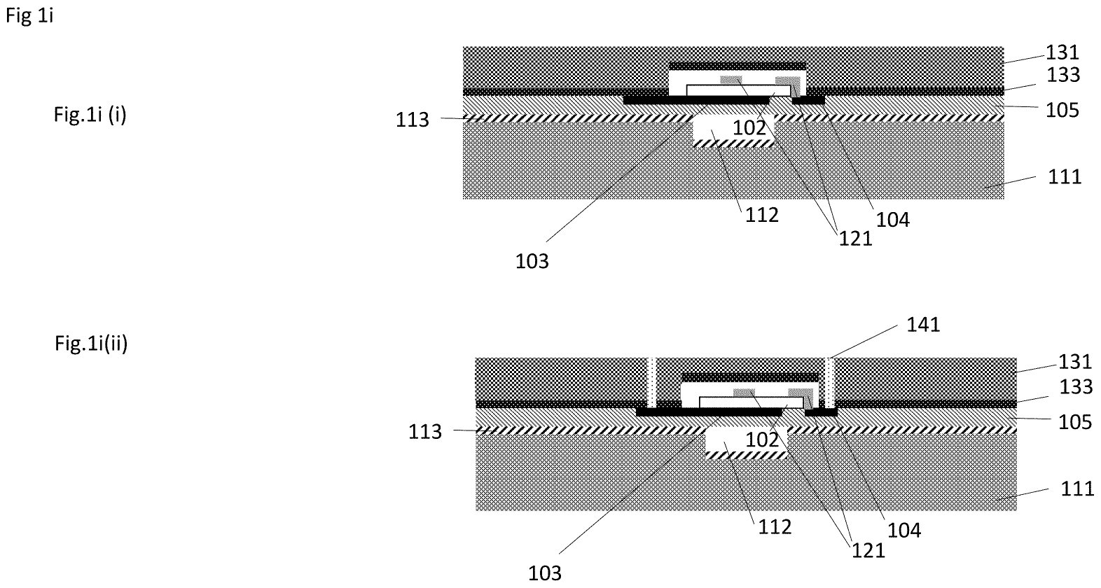

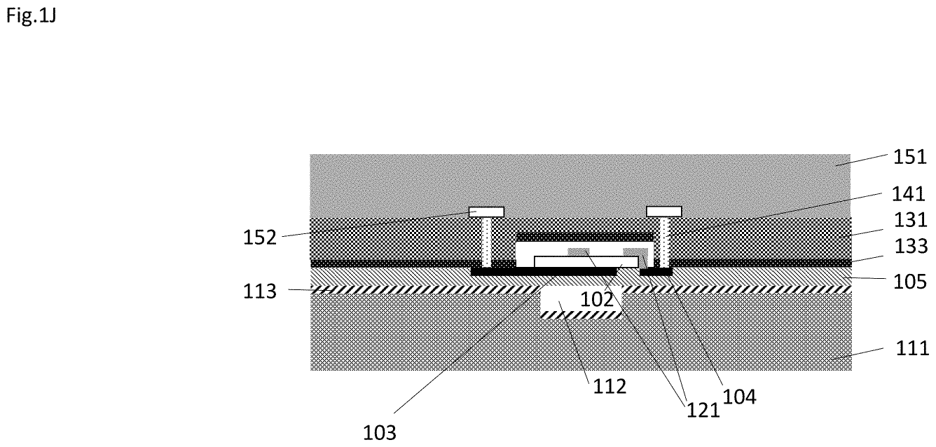

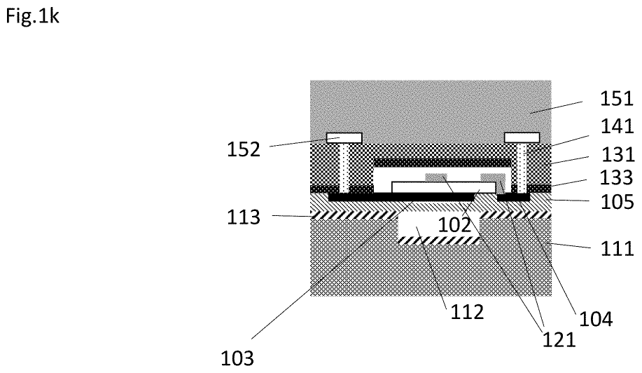

FIGS. 1a(i-iv) describe an embodiment of a process flow to prepare the piezoelectric single crystal wafer for targeted BAW device thickness via wafer to wafer bonding to make BAW devices in this invention. Although there is only one device is drawn here, cross wafer die-repeatability is expected so that many devices can be made at the same time to reduce fabrication cost.

FIG. 1a(i) shows an incoming piezoelectric single crystal wafer 101. FIG. 1a(ii) shows the ion cut process eg. smart cut for a targeted piezoelectric material thickness for BAW. 102 is the ion implanted layer with a targeted thickness. Basically, for the targeted piezoelectric thickness, a right implantation ion with preset ion implantation parameters such as implantation tilting angle, energy, and dosage needs to be carefully controlled. The stress induced by the implantation will lead to the full cleave of the single crystal piezoelectric material with the thickness very close to the targeted thickness. FIG. 1a(iii) shows the bottom electrode(s) (103) and bottom lead(s) (104) patterning, post which the bonding layer 105 is deposited or coated cross the whole wafer as shown in FIG. 1a(iv). Till FIG. 1a(iv), the piezoelectric single crystal wafer preparation is done.

FIG. 1b is an embodiment of bottom substrate wafer processing for wafer bonding preparation, which includes incoming wafer 111 (as shown in FIG. 1b (i), the creation of the cavity 112 (as shown in FIG. 1b(ii)) for BAW devices, and bonding layer 113 (as shown in FIG. 1b(iii) coverage cross wafer. The creation of cavity can be made by either reactive ion etching (RIE), or wet etch, or other alternatives methods.

FIG. 1c is an embodiment of the face-to-face wafer to wafer bonding using the prepared wafers shown in FIG. 1a(iv) and FIG. 1b(iii). The cavity 112 is vacuum sealed, which can minimize the acoustic energy loss from the bottom of the device.

FIG. 1d is an embodiment of the so-called ion cut process eg. smart cut, through annealing, which induces the stress to remove the piezoelectric single crystal substrate for reuse. Then CMP or wet etch is used to remove high doped area while healing the potential damage in the crystal structure in the remaining layer with a targeted thickness for the BAW device.

FIG. 1e shows the final results of a patterned pizeo material with a desired device size using litho-steps and piezoelectric material RIE. It is also noticeable that the bottom lead(s) 104 is close to the edge of the patterned BAW device for later connection to a top electrode in the following illustration. The above litho-steps and RIE processes can be repeated several times to achieve different piezoelectric material thicknesses at different locations for a targeted RF frequency filtering; within a filter chip containing multiple BAW filter devices.

FIG. 1f is an embodiment of the process to form the top electrode 121 and its connection to the bottom lead 104 through a combination of litho, metal deposition and liftoff processes. The top electrode and the connection share the same label of 121 as they are the same material through the same process steps to reduce the cost.

FIG. 1g is an embodiment of the process to make a cap wafer 131 (as shown in FIG. 1g(i) which includes forming a cavity 132 in the cap wafer as shown in FIG. 1g(ii) followed by deposition of a bonding layer 133 as shown in FIG. 1g(iii).

FIG. 1h is an embodiment of the wafer bonding process between the finished cap wafer 131 as shown in FIG. 1g(iii) and the wafer with device described in FIG. 1f. The wafer bonding process is done with a pre-vacuum pumping down process to ensure the BAW device's top cavity 132 is in vacuum, which can dramatically reduce the acoustic energy loss through the top of the electrode and/or through top surface of the BAW device.

FIG. 1i is an embodiment of the cap wafer thinning process FIG. 1i(i) followed by process FIG. 1i(ii) to generate through via 141. If the cap wafer is a silicon wafer then the through via is a through silicon via named TSV. Of course, the through via 141 eg TSV can also be done inside the cap wafer before wafer bonding. If that is the case, the process flow does need some slightly adjustment, which is well known by an expert in the field. Therefore, there is no need to describe in details here. The through via 141 eg. TSV connect the bottom electrode(s) and bottom lead(s) to the backside of the cap wafer, which enables wafer bonding of an electrical wafer to the BAW device wafer, enabling a full heterogeneous integration of e-chips with BAW devices to form a full RF front of end chip, as illustrated in FIG. 1j. Wafer bonding between e-chip wafer 151 and FBAR wafer is done via Joint 152 and interface between wafer 151 and wafer 131. Joint 152 can be formed by metal to metal direct bonding or hybrid bonding, or eutectic bonding, or conductive epoxy. After bonded wafers dicing, a single die with heterogeneously integrated e-chip(s) and BAW device(s) is obtained as described in FIG. 1k.

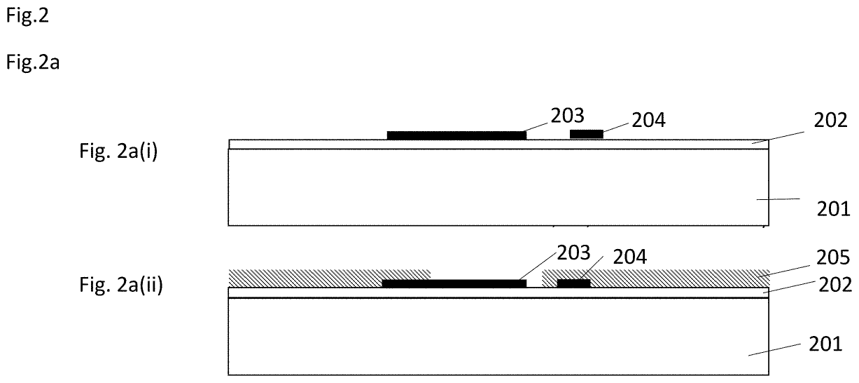

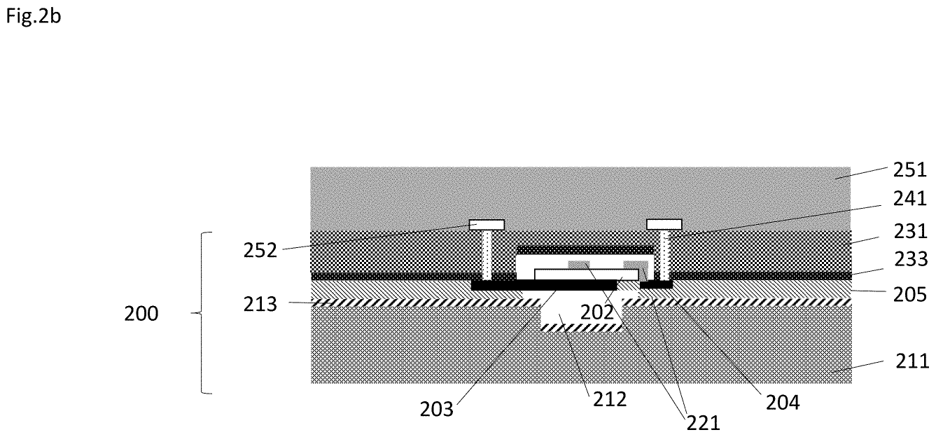

FIG. 2a is an embodiment of process flow very similar to what has been described in FIG. 1a but adding some extra process steps to do some litho steps before and the liftoff process after bonding layer deposition. In detail, ion cut is used to generate thin cut 202 in a single crystal piezoelectric wafer eg single crystal wafer of AlN, ZnO etc., then bottom electrode(s) 203 and bottom lead(s) 204 are formed by metal deposition and liftoff process as shown in FIG. 2a(i). A liftoff process can then be used to add bonding layer 205 cross whole wafer but avoid covering the area directly below bottom electrodes to further reduce the acoustic energy loss and improve the BAW device performance as shown in FIG. 2a(ii).

FIG. 2b is an embodiment of the schematic drawing of finished wafer bonding between an e-chip wafer 251 and a BAW device wafer 200 via joint 252 and electrical connection 241, which is very much similar to what is shown in FIG. 1J. Joint 252 can be formed by metal to metal direct bonding or hybrid bonding, or eutectic bonding, or conductive epoxy. The BAW device wafer 200, also formed through wafer bonding between cap wafer 231 and substrate 211 via two bonding interfaces between bonding layers 233 and 205, then layers 205 and 213. On the top of wafer 211, a piezoelectric single crystal wafer with BAW device(s) including bottom electrode(s) 203, bottom lead(s) 204, patterned piezoelectric material 202, top electrode 221, is built via face-to-face (wafer-to-wafer) bonding between bonding layers 205 and 213.

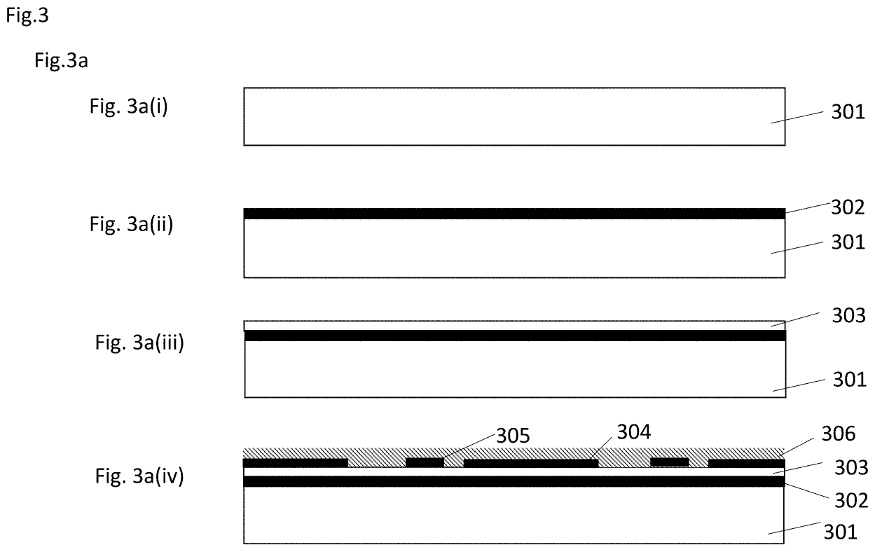

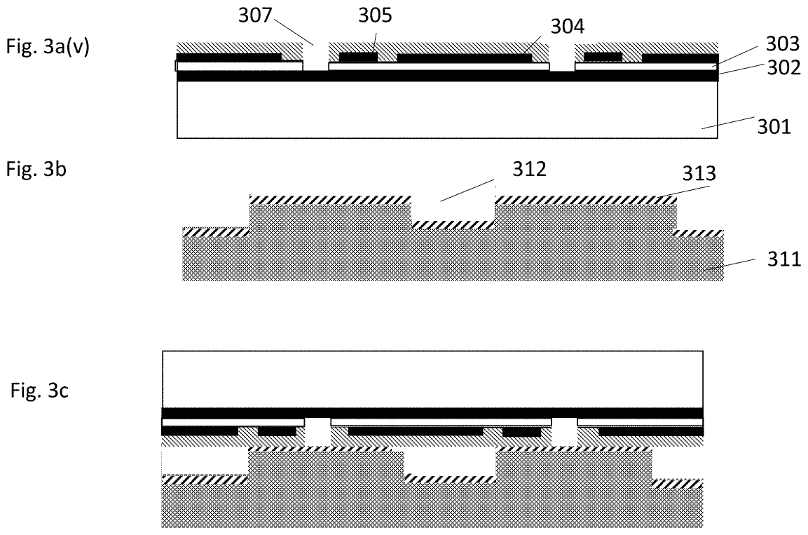

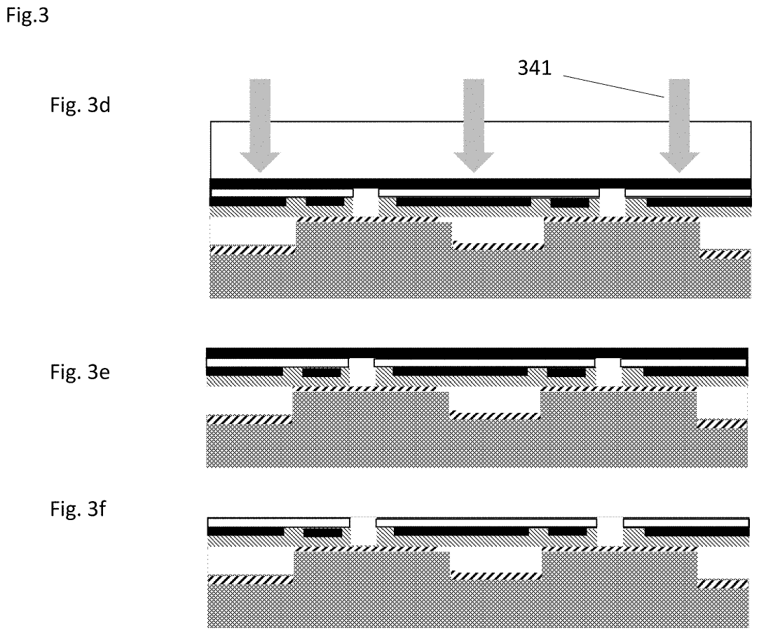

FIG. 3a shows one of the embodiments using a single crystal piezoelectric wafer with correct orientation for BAW devices as an template for AlN film 303 growth on an epi seed layer 302, which also acts as a detachable “glue layer” during later laser transfer process (or laser lift-off process). Of course, alternative method such as transfer print can be used as well for the die to wafer transfer similar to what is described here with slightly modification. In details, in FIG. 3a(i) a single crystal piezoelectric wafer 301 is used as an epitaxy growth template, on which an epitaxy(epi) seed layer 302 acting also as the release layer for later BAW die release is deposited, as shown in FIG. 3a(ii). The choice of the epi seed layer needs to be careful to ensure the single crystal piezoelectric wafer's crystal structure can transfer without much loss to the follow-up piezoelectric layer 303 with a targeted thickness for BAW device through epi-growth. In terms of the material composition and crystal orientation, the layer 303 should be the same as template wafer 301 as shown in FIG. 3a(iii). On top of the piezoelectric-layer 303, as shown in FIG. 3a(iv), bottom electrode(s) 304 and bottom lead(s) 305 are fabricated followed by the deposition of a bonding layer 306. FIG. 3a(v) shows an embodiment of the single device isolation through generating device isolation trenches 307. The purpose of trenches 307 isolate the device's piezoelectric-layer 303 along with its bottom electrode 304 and bottom lead 305 but without going through seed/release layer 302 so that the substrate 301 is not touched or get damaged. The device isolation provides great help to later single crystal substrate detachment and allows the isolated device transfer to substrate shown in FIG. 3b. FIG. 3b is an embodiment of the other substrate wafer for the incoming wafer-to-wafer bonding to make the BAW devices. As shown in FIG. 3b, on the substrate wafer 311, there are recessed trenches 312 made for the BAW devices' bottom cavity while a bonding layer 313 is implemented cross the whole wafer 311. FIG. 3c is an embodiment of the face-to-face wafer-to-wafer bonding of the two wafers shown in FIG. 3a(v) and FIG. 3b. The bonding is made with pre-vacuum pumping to ensure low pressure in the cavity 312, which helps to minimize the acoustic energy loss of the BAW device from the bottom cavity. After that, the process continues with a single crystal wafer release process. There are many alternatives and prior arts for the wafer release known to people with expertise in the field. In this embodiment shown in FIG. 3d, a laser liftoff process (with laser beam 341), with either one step or multiple laser process steps/scans, is used to detach the single crystal piezoelectric wafer from the seed/glue layer 302 with the end result shown in FIG. 3e followed by seed/glue layer 302 removal, which leaves the isolated patterned piezoelectric layers on top of the cavities 312, as shown in FIG. 3f. From the FIG. 3f upwards, the process can be resumed similar to the process step described from FIG. 1d onwards with slight modification, which is well known for the people working in the field. Although the lift-off process for releasing the single crystal piezoelectric wafer from the seed/glue layer 302 is shown here as an example, there are other alternatives such as chemical liftoff process and stressed induced liftoff can be used here.

Although the previously described wafer-to-wafer approach is capable of making the multiple BAW devices aiming for different frequency bands on the same die or die package via introducing extra wafer processes to target different thicknesses for the piezoelectric layer on an individual die, the process flow which involves litho and precise RIE process for thickness targeting is expensive. In the subsequent section, a die-to-wafer integration scheme for fabricating BAW devices is introduced, which allows dies with dedicated piezoelectric material thickness made before the bonding process and enable simple and overall cheaper approach for multiple BAW devices in one die or in one chiplet.

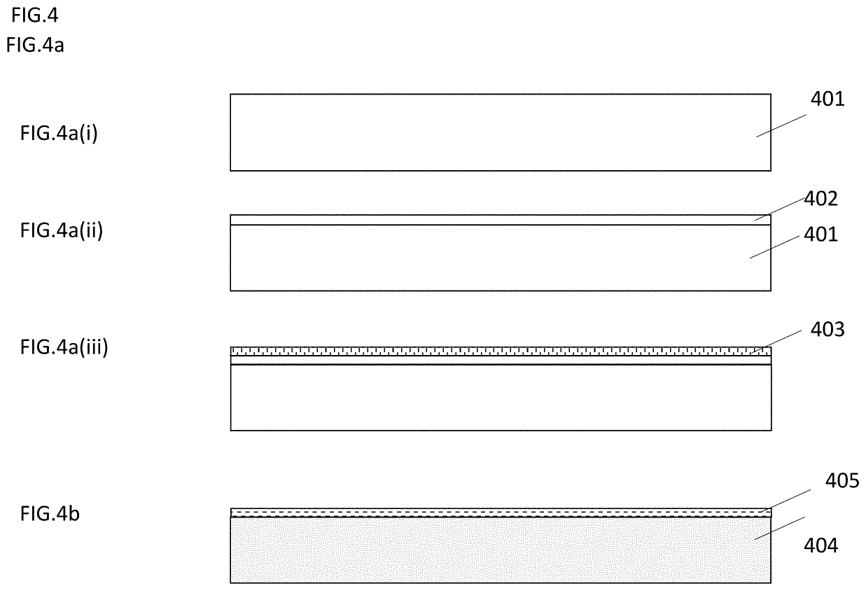

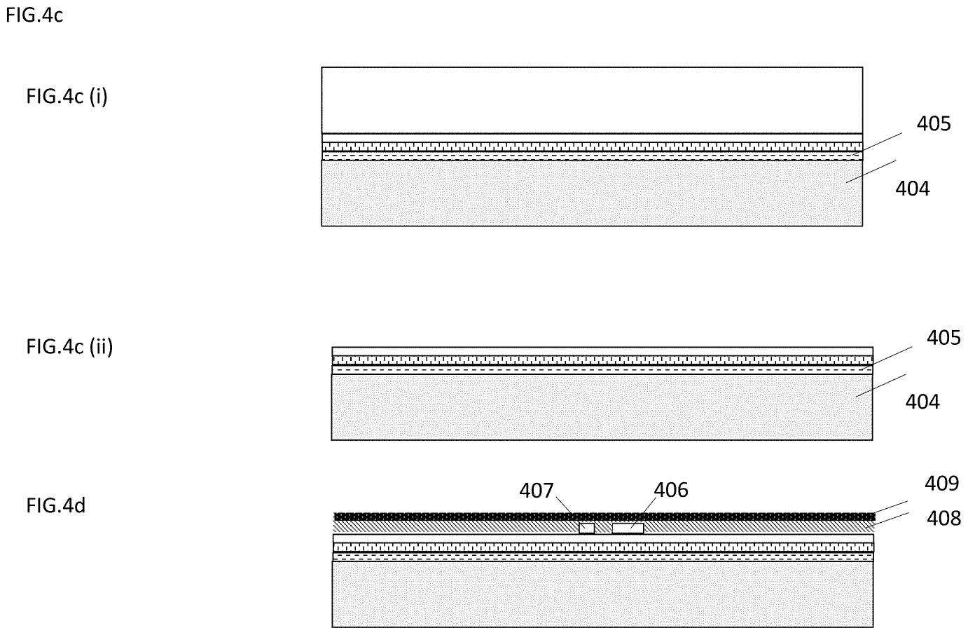

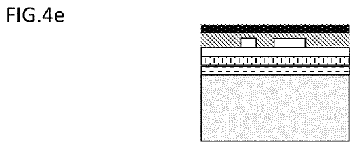

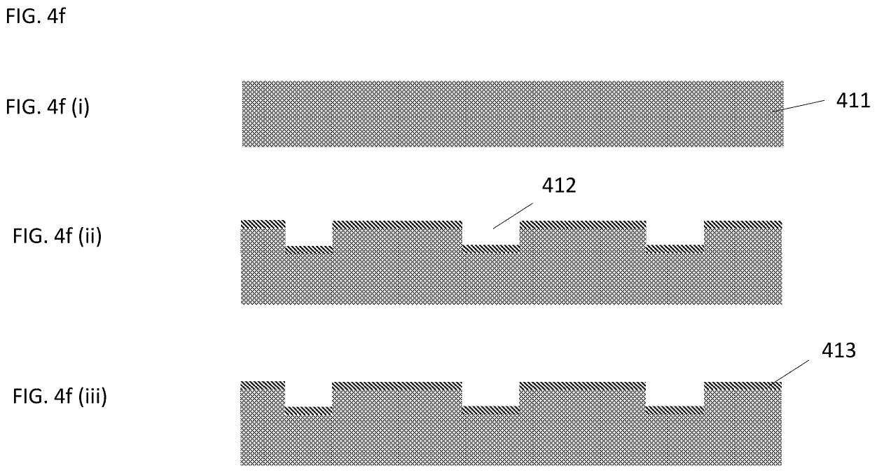

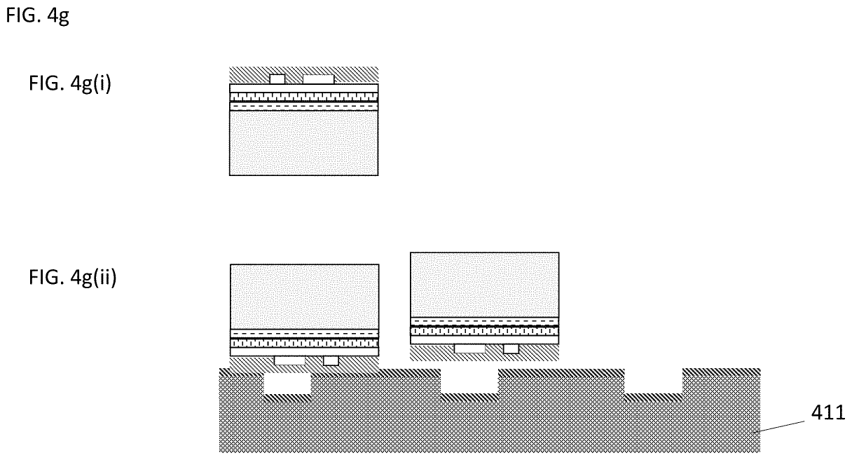

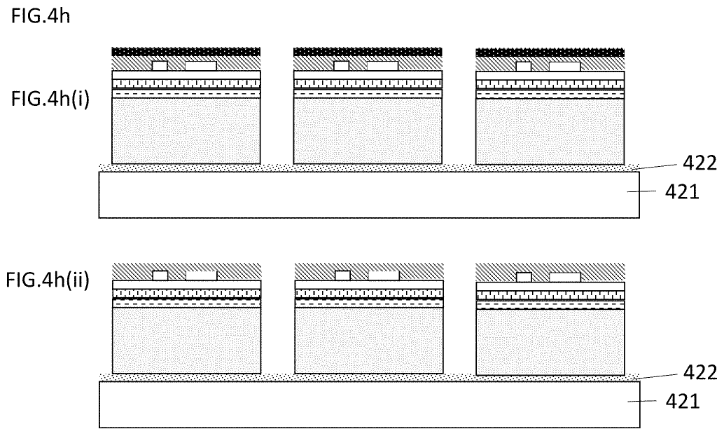

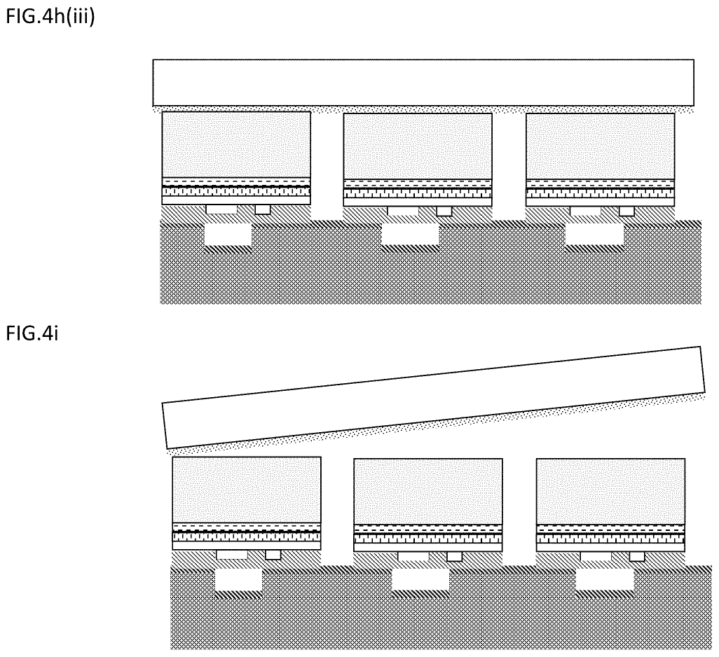

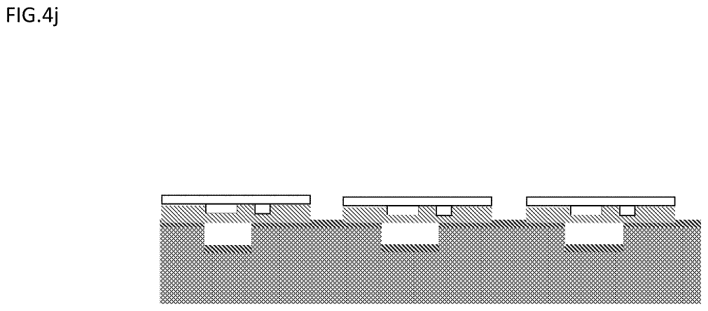

FIG. 4 shows an embodiment of the process flow to fabricate BAW devices from single crystal piezoelectric wafer using die to wafer approach. FIG. 4a(i) and FIG. 4a (ii) are very much similar to FIG. 1a(i) and FIG. 1a(ii), 401 is the single crystal piezoelectric wafer, on which 402 the ion implanted layer is made through ion implantation such as H2 implantation, which is later used to separate 402 from 401 through ion cut process. To enable reuse of the single crystal wafer 401, an extra bonding layer 403 is coated cross the top of the layer 402 as shown in FIG. 4a(iii). FIG. 4b shows an embodiment to prepare a handling wafer 404 with a bonding layer 405, which will be used to bond to layer 403 as shown in FIG. 4c(i). In some case, either 403 or 405 cab be use along without the need of the pair for bonding between wafer 401 and handling wafer 404. Layer transfer process is described in FIG. 4c(ii) through cut ion process to get the single crystal wafer 401 detached. Wafer 401 can then be re-used. After the success of detachment of wafer 401, the bottom lead 406 and bottom electrodes 407 are built then covered by bonding layer 408 and dicing protection layer 409 similar to but no exact the same as what has been described in FIG. 1a(iv). Although there is only one die was drawn here, there are many dies similar to what was shown here. After that, the handling wafer 404 with all the dies is diced into individual dies as shown in FIG. 4e. It is noticeable, the thickness of 402 shown in FIG. 4a can be varied targeting for filtering of different frequency bands on wafer similar to 401. FIG. 4f is very much similar to what has been described in FIG. 1b, which is about substrate wafer preparation for the BAW needed bottom cavity 412 as shown in FIG. 4f(ii) formed in wafer 411 (as shown in FIG. 4f(i) together with bonding layer 413 cross the whole wafer with the finished result shown in FIG. 4f(iii). After removing the protection layer shown in FIG. 4e, the die shown in FIG. 4g(i) is ready for die to wafer bonding, as shown in FIG. 4g(ii). Note, dies from different singe crystal piezoelectric wafers 401 with targeted different thicknesses of the piezoelectric layer 402 can be assembled on the same substrate wafer 411 as shown in FIG. 4g(ii). There is an alternative way, namely collective die-to-wafer bonding method, which is described in FIG. 4h, to bond the piezoelectric layer 402 on top of the cavity 412 on substrate 411. In details, the individual die shown in FIG. 4e is temporarily bonded on carrier wafer 421 via bonding layer 422 as shown in FIG. 4h(i). Then the dicing protection layer 409 is removed from the dies as shown in FIG. 4h(ii). The whole carrier wafer 421 with bonded dies whose dicing protection layer already removed is then flipped and bonded on top of the substrate wafer 411 with some alignment to ensure the die with piezoelectric layer landing on top of the cavity for BAW device as shown in FIG. 4h(iii) followed by carrier wafer 421 de-bond as shown in FIG. 4i. Then all the extra layers on top of the piezoelectric layers get removed to reach the state as shown in FIG. 4j, from which the process flow can be further carried out as process step similar to what has been shown in FIG. 1k upwards to finish the BAW device manufacture process with e-chip and packaging included.

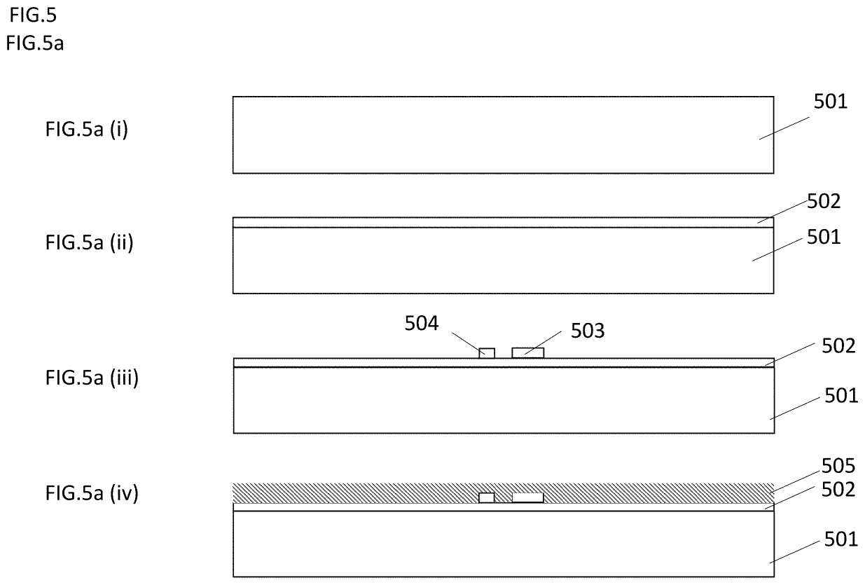

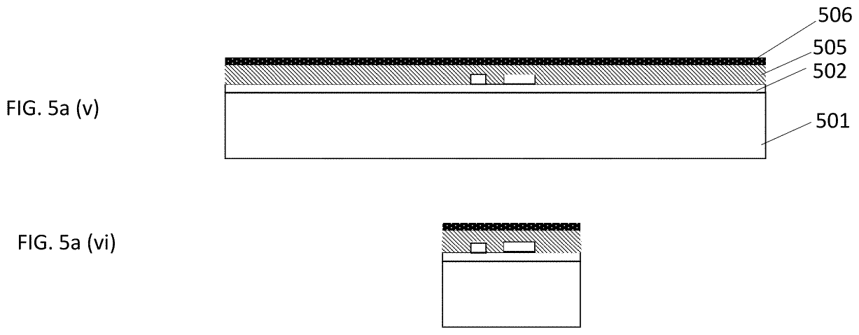

FIG. 5 shows an embodiment of a process flow, in which a single crystal piezoelectric wafer is directly used then diced to create the piezoelectric die for enabling die to wafer bonding process to make BAW devices. The direct use and dicing of single crystal piezoelectric wafer is current a very expensive choice. Nevertheless, it could become a process of choice provided the cost of the single crystal piezoelectric wafer such as AlN is much greatly reduced due to the other applications in the incoming wide band semiconductor applications. In terms of the process details, as shown in FIG. 5a, the ion implantation process is used on the singe crystal piezoelectric wafer 501 shown in FIG. 5a(i) to form layer 502, for an incoming ion cut process. Then bottom lead 503 and bottom electrode 504 are made in the same process such as metal deposition and liftoff as shown in FIG. 5a(iii), after which a bonding layer 505 is implemented cross whole wafer as shown in FIG. 5a(iv). Then a dicing protection layer 506 is coated on top of the wafer 501 to protect the bonding layer 505 as shown in FIG. 5a(v). After dicing of the wafer 501, the die as shown in FIG. 5(vi), going through the dicing protection layer 506 removal as shown in FIG. 5b(i), is then ready for die to wafer bonding as shown in FIG. 5b(ii). The process flow can follow what has been already shown from FIG. 4i upwards with slight modifications for one who is familiar with art in the field.

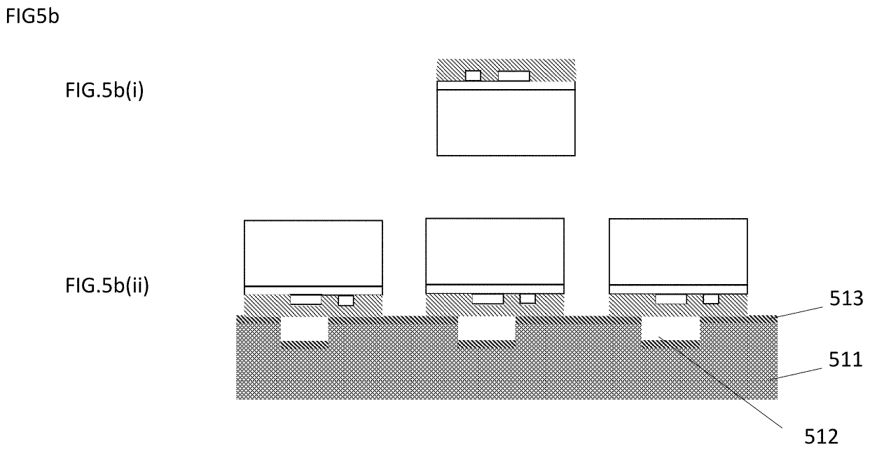

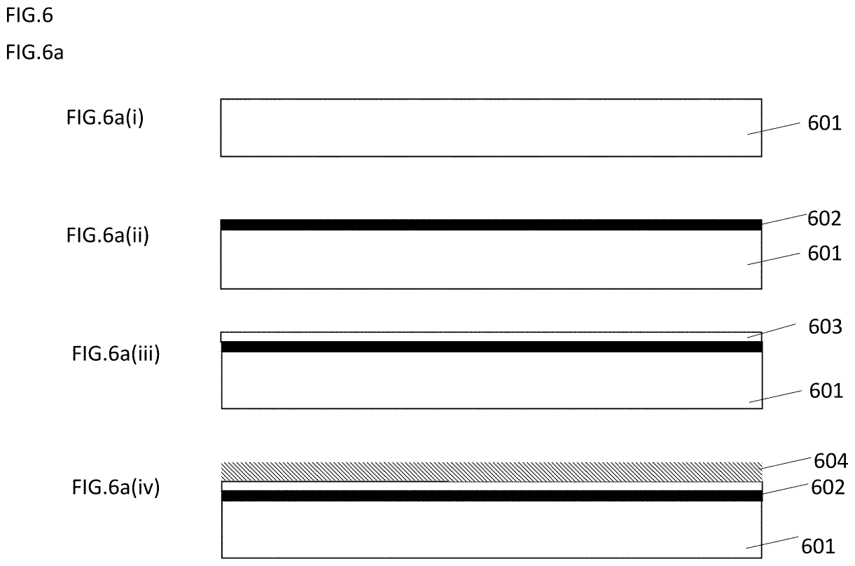

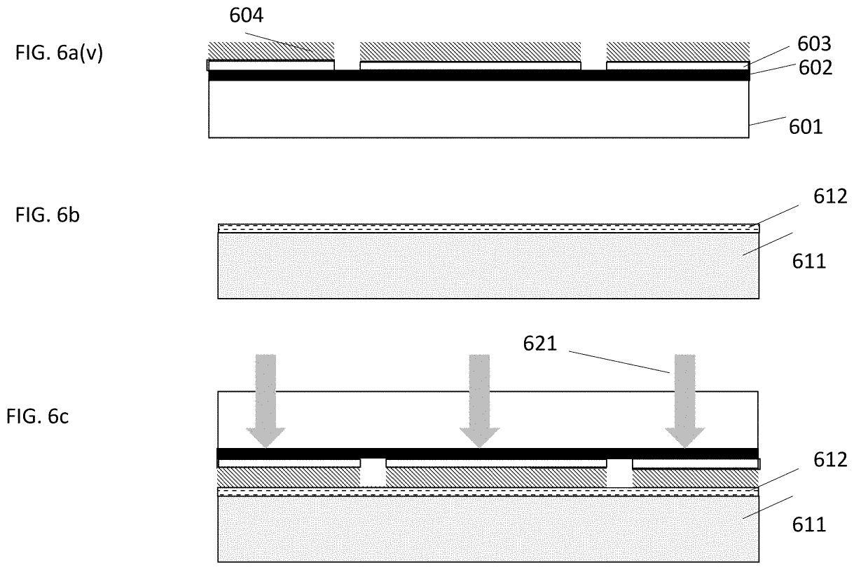

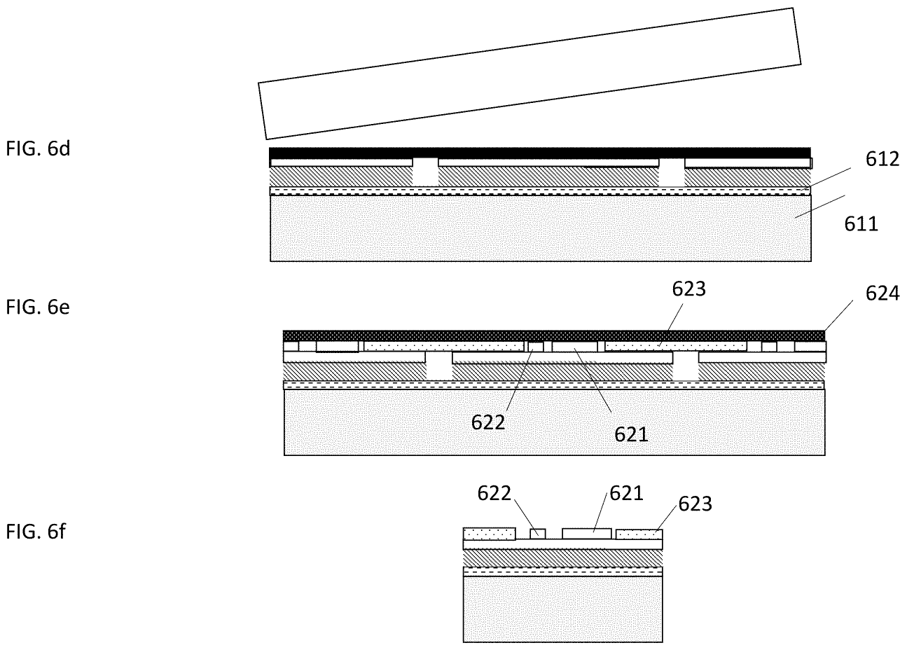

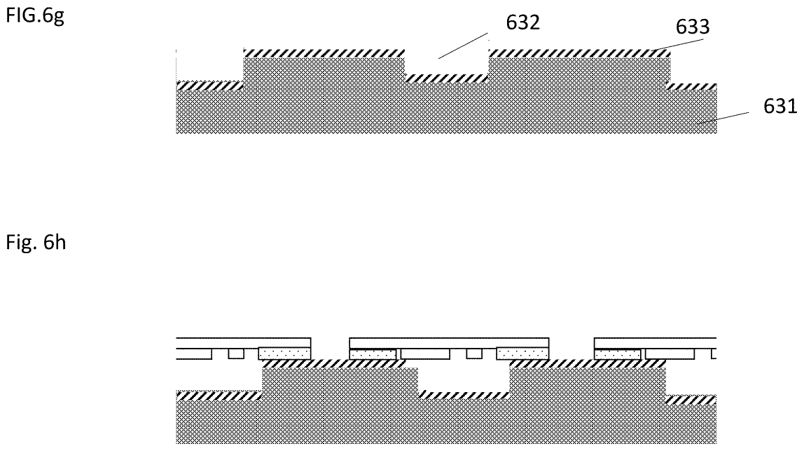

FIG. 6 is an embodiment of the die-to-wafer version in comparison with the wafer to wafer version as what has been shown in FIG. 3. In details, a single crystal piezoelectric wafer 601 as in FIG. FIG. 6a(i) is covered with a seed/release layer 602 which serves two purposes: firstly acting as a release layer; secondly extending the crystal structure from the single crystal piezoelectric to the piezoelectric functional layer 603 as shown in FIG. 6a(iii). Compared to normal substrates such as amorphous substrates, using the single crystal piezoelectric wafer with the right crystal orientation provide great improvement in terms of crystallinity and right orientation for the functional piezoelectric layer 603. As shown in FIG. 6a(iv), the whole wafer is covered by bonding layer 604 followed by device isolation as shown in FIG. 6a(v). FIG. 6b shows an embodiment of handling wafer 611 with bonding layer 612 on top. FIG. 6c shows the process of wafer bonding followed by laser liftoff process to transfer the piezoelectric function layer 603 on the handling wafer 611 with the help of laser energy from the laser beam 621. Although the laser liftoff is illustrated here as a process of choice for the transfer of the function layer 603, there are many alternatives process choices such as wet etch, vapor liftoff, transfer print, which could be used to enable the transfer of the function layer 603. The original single crystal piezoelectric substrate is then removed as shown in FIG. 6d, followed by the glue/seed layer 602 removal then fabrication of bottom lead(s) 621 and bottom electrode(s) 622. 623 is the bonding layer which is covered by a dicing protection layer 624 as shown in FIG. 6e. After dicing and dicing protection layer 624 removal, the die shown in FIG. 6f is ready for die to wafer bonding. FIG. 6g is the BAW device substrate preparation very much similar to what has been shown in FIG. 4f. In details, trench 632, which is used as BAW device's bottom cavity, is created in substrate 631, then bonding layer 633 is deposited. After the wafer to wafer bonding similar to what has been described as in FIG. 1c, followed by the substrate removal, the piezoelectric functional layer with bottom lead and electrode is successfully transferred on the top of its corresponding trench as shown in FIG. 6h, from which step the process can continue by following what have been shown already from FIG. 1d onwards to make a full BAW device with e-chips and packaging.

What is claimed is:

1. An acoustic wave device system comprises at lease:
A piezoelectric functional layer/element obtained by a method originating from a single crystal piezoelectric wafer/substrate;
A substrate wafer to support the piezoelectric functional layer/element;
A cap wafer to encapsulate the piezoelectric functional layer/element;
A part of electrodes;
A bonding method to permanently join the piezoelectric functional layer/element to the substrate wafer.

2. The system of claim 1, wherein said pair of electrodes comprises a bottom electrode below and a top electrode above said piezoelectric functional layer/element, in which an acoustic wave is generated between the pair.

3. The system of claim 1, wherein said method is to split said piezoelectric functional layer/element by an ion cut process from said single crystal piezoelectric wafer/substrate.

4. The system of claim 1, wherein said method is to epitaxially grow said piezoelectric functional layer/element on top of a glue/release layer over said single crystal piezoelectric wafer/substrate, followed by a release process to detach the piezoelectric functional layer/element.

5. The system of claim 1, wherein said substrate wafer has at least a cavity, inside which vacuum is maintained and over which said piezoelectric layer/element locates to minimize acoustic energy loss from the bottom of said piezoelectric functional layer/element.

6. The system of claim 1, wherein said cap wafer has at least a cavity, which is maintained a vacuum inside and locates on the top of said piezoelectric functional layer/element to minimize the acoustic energy loss from the top of the device.

7. The system of claim 1, wherein said cap wafer is bonded on the top of said substrate wafer via a wafer-to-wafer bonding process.

8. The system of claim 1, wherein said cap wafer has an group of through-wafer-via which provide electrical connections to said acoustic wave device system from outside.

9. The system of the claim 8, wherein said group of through-wafer-via connect to at least an electrical chip on top of said cap layer through either wafer-to-wafer or die-to-wafer bonding.

10. The system of the claim 8, wherein said group of through-wafer-via connect to an outside electrical circuit through wire bonding technology.

11. The system of the claim 1, wherein said bonding method is a wafer-to-wafer bonding technology between said substrate wafer and said single crystal piezoelectric wafer/substrate through a pair of bonding layers.

12. The system of the claim 11, wherein said pair of wafer bonding layers do not cover the pair of electrodes of the acoustic wave device system.

13. The system of the claim 11, wherein said pair of wafer bonding layers consists of a bonding layer on the substrate wafer and a bonding layer over the piezoelectric function layer/element either split by a ion cut process or released by a liftoff process from the single crystal piezoelectric wafer/substrate.

14. The system of the claim 1, wherein said bonding method is a wafer-to-wafer bonding technology between said substrate wafer and a carrier wafer, on which a collection of dies with the piezoelectric functional layer/element are assembled one-by-one through a die-to-wafer bonding technology.

15. The system of the claim 1, wherein said bonding method is a die-to-wafer bonding technology between said substrate wafer and a group of dies providing said piezoelectric functional layer/element.

16. The system of the claim 15, wherein said group of dies is obtained by dicing a single crystal piezoelectric wafer with an ion implanted layer, which is capable of being separated by a ion cut process to provide the piezoelectric functional layer/element.

17. The system of the claim 15, wherein said group of dies is obtained by dicing a handling wafer, on which there is the piezoelectric functional layer/element transferred from a single crystal piezoelectric wafer via a wafer-to-wafer bonding, between the handling wafer and the single crystal piezoelectric wafer, followed by an ion cut process to split the piezoelectric functional layer/element.

18. The system of the claim 15, wherein said group of dies is obtained by dicing a handling wafer, on which there is the piezoelectric functional layer/element, which is epitaxially grown on top of a release/glue layer over a single crystal piezoelectric wafer and is later released via a layer/element release process.

19. The system of the claim 18, wherein said layer/element release process is either a laser liftoff process, or a chemical liftoff process, or a stress induced liftoff process, or the combination of the above mentioned liftoff processes.

20. The system of claim 4, wherein said release process is either a laser liftoff process, or a chemical liftoff process, or a stress induced liftoff process, or the combination of the above mentioned liftoff processes.
